(19) United States
(12) Patent Application Publication
(10) Pub. No.: US 2016/0254043 A1
(43) Pub. Date: Sep. 1, 2016

(54) SEMICONDUCTOR MEMORY DEVICE AND METHOD OF OPERATING THE SAME

(71) Applicant: SK hynix Inc., Gyeonggi-do (KR)

(72) Inventor: Jong-Yeol YANG, Gyeonggi-do (KR)

(21) Appl. No.: 14/827,117

(22) Filed: Aug. 14, 2015

(30) Foreign Application Priority Data
Feb. 27, 2015 (KR) 10-2015-0028007

(51) Int. Cl. G11C 11/406; G11C 17/18; G11C 29/00; G11C 17/16

(52) U.S. Cl. CPC G11C 11/40615; G11C 17/16; G11C 17/18; G11C 11/40611; G11C 29/76; G11C 29/78

(57) ABSTRACT

A semiconductor memory device includes a refresh cycle generation unit capable of generating a first cycle signal and a second cycle signal having a cycle shorter than the first cycle signal; and a refresh control unit capable of generating a plurality of row addresses based on the first or second cycle signal.

### CROSS-REFERENCE TO RELATED APPLICATIONS

The present application claims priority of Korean Patent Application No. 10-2015-0028007, filed on Feb. 27, 2015, which is incorporated herein by reference in its entirety.

### BACKGROUND

1. Field

Exemplary embodiments of the present invention relate to a semiconductor design technology and, more particularly, to a semiconductor memory device for performing a refresh operation.

2. Description of the Related Art

Semiconductor memory devices include memory arrays and redundancy memory arrays for repair. Memory cell arrays may have defective memory cells that occur during manufacturing. Redundancy memory arrays include redundancy memory cells used to replace memory cells that are defective.

When the wafer manufacturing process has been completed, tests are performed to determine if any of the memory cells have defects. After the tests, memory cells that are found to be defective are replaced by redundancy memory cells while the semiconductor device is still in the wafer state wafer. Further repairs, called post package repairs (hereinafter, referred to as a “PPR”), are performed after the semiconductor memory devices have been packaged. Memory cells that are found to be defective after packaging are repaired using an electrical fuse circuit, e.g., an array E-fuse (ARE), further improving the overall yield.

Semiconductor memory devices perform refresh operations to recover data stored in memory cells before it is lost. Only one bank at a time can operate in PPR mode, and the other banks perform refresh operations according to a refresh command that is provided from an external source. However, since the refresh operations are performed during a PPR mode according to an external refresh command, the repair operations may not be appropriately performed. For this reason, in a PPR mode, during a boot-up period and a program period for programming (i.e., rupturing) an array E-fuse using fail addresses, the refresh command is blocked so that refresh operations are not performed, and the refresh operations are performed after the boot-up period until the PPR mode is terminated. As described above, with respect to banks other than a bank performing a PPR operation, refresh operations are not performed during a program period and a boot-up period, so that data reliability may deteriorate.

### SUMMARY

Various embodiments are directed to a semiconductor memory device capable of performing a refresh operation even in a PPR mode.

In an embodiment, a semiconductor memory device may include: a refresh cycle generation unit capable of generating a first cycle signal and a second cycle signal having a cycle shorter than the first cycle signal; and a refresh control unit capable of generating a plurality of row addresses based on the first or second cycle signal.

The refresh control unit may receive a refresh signal, a post package repair mode signal and an idle signal.

The refresh control unit may include: a refresh cycle control unit capable of outputting the first or second cycle signal as an internal refresh cycle signal based on the post package repair mode signal and the idle signal; and a refresh counter capable of generating the row addresses to perform refresh operations based on the internal refresh cycle signal.

The refresh cycle control unit may include: an internal refresh signal generation unit capable of generating an internal refresh signal based on the post package repair mode signal and the idle signal; and an internal refresh cycle generation unit capable of outputting the first or second cycle signal based on the internal refresh signal,

The semiconductor memory device may further include: a fuse array control unit capable of generating the idle signal and a program signal based on the post package repair mode signal; and a fuse array capable of performing program and boot-up operations based on the program signal and a boot-up signal.

The idle signal may be activated when the program signal and boot-up signal are deactivated and until the post package repair mode signal is deactivated.

The refresh signal may include an auto-refresh signal and a self-refresh signal.

The semiconductor memory device may further include: a command control unit capable of generating the refresh signal and the post package repair mode signal based on an external command.

In an embodiment, a method of operating a semiconductor memory device may include: generating a program signal and an idle signal based on a post package repair mode signal; programming a fuse array according to fail addresses based on the program signal; performing a boot-up operation on the fuse array; and performing refresh operations using a first cycle signal or a second cycle signal having a cycle shorter than the first cycle signal, based on the post package repair mode signal and the idle signal.

The performing of the refresh operations may include: selecting the first or second cycle signal to output an internal refresh cycle signal based on the post package repair mode signal and the idle signal; and generating a plurality of row addresses to perform the refresh operations based on the internal refresh cycle signal.

The selecting of the first or second cycle signal may include: generating an internal refresh signal based on the post package repair mode signal and the idle signal; and selecting the first or second cycle signal based on the internal refresh signal to output the internal refresh cycle signal.

The method may further include: generating the first cycle signal and the second cycle signal.

In an embodiment, a semiconductor memory device may include: a refresh cycle generation unit capable of generating a first cycle signal and a second cycle signal having a cycle shorter than the first cycle signal; a fuse array capable of being programmed according to fail addresses during a program period, and performing a boot-up operation during a boot-up period; and a refresh control unit capable of performing refresh operations using the second cycle signal during an idle period in a post package repair mode.

In a post package repair mode, the refresh operations may be not performed during the program and boot-up periods.

In a normal operation, the refresh operations mays be performed using the first cycle signal.

### BRIEF DESCRIPTION OF THE DRAWINGS

FIG. 1 is a block diagram illustrating a semiconductor memory device in accordance with an embodiment of the present invention;

FIG. 2 is a detailed diagram of a refresh cycle control unit shown in FIG. 1; and

FIG. 3 is a timing diagram for describing an operation of the semiconductor memory device shown in FIG. 1,

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts in the various figures and embodiments of the present invention.

The drawings are not necessarily to scale and, in some instances, proportions may have been exaggerated to clearly illustrate features of the embodiments. It is also noted that in this specification, “connected/coupled” refers to one component not only directly coupling another component but also indirectly coupling another component through an intermediate component. In addition, a singular form may include a plural form as long as it is not specifically mentioned.

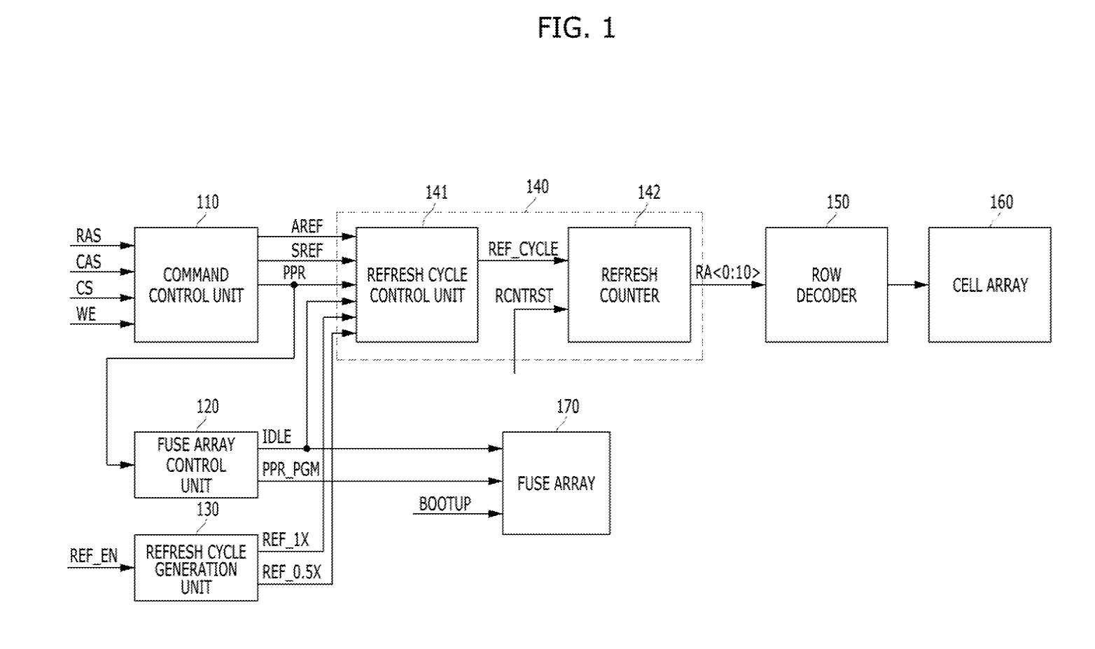

FIG. 1 is a block diagram illustrating a semiconductor memory device in accordance with an embodiment of the present invention.

Referring to FIG. 1, the semiconductor memory device may include a command control unit 110, a fuse array control unit 120, refresh cycle generation unit 130, a refresh control unit 140, a row decoder 150, a cell array 160, and a fuse array 170.

The command control unit 110 may decode commands RAS, CAS, CS and WE inputted from outside (e.g. a host or external device), and generate an auto-refresh mode signal AREF, a self-refresh mode signal SREF, and a post package repair mode signal PPR (hereinafter, referred to as a “PPR mode signal”). For reference, the “CS” represents a chip selection signal; the “RAS” represents a row address to strobe signal, and enables a row operation of the semiconductor memory device; the “CAS” represents a column address strobe signal, and enables a column operation of the semiconductor memory; and the “WE” represents a write enable signal, and enables to determine whether data is to be written to or read from the semiconductor memory device.

In addition, the auto-refresh mode signal AREF indicates an auto-refresh mode where a refresh operation is performed by applying a refresh command from outside of the semiconductor memory device during the operation of the semiconductor memory device. The self-refresh mode signal SREF indicates a self-refresh mode where a refresh operation is performed by autonomously generating a refresh command within the semiconductor memory device when the semiconductor memory device does not operate. In addition, the PPR mode signal PPR indicates a PPR mode where a repair operation is performed after the semiconductor memory device has been packaged.

Although it is not shown, the command control unit 110 may include a command decoder and a mode register set (MRS). The command control unit 110 may generate the mode signals AREF, SREF and PPR, an active command, and a precharge command.

The fuse array control unit 120 may generate a PPR program signal PPR_PGM and an idle signal IDLE in response to the PPR mode signal. The PPR program signal PPR_PGM controls the rupture of fuses corresponding to fail addresses (not shown) inputted to the semiconductor memory device in the post package repair mode. The idle signal IDLE denotes an idle period, and, in a PPR mode, is activated when a program operation and a boot-up operation is completed and until the PPR mode is terminated in response to the PPR program signal PPR_PGM and a boot-up signal BOOTUP.

The refresh cycle generation unit 130 may generate a first cycle signal REF_1X and a second cycle signal REF_0.5X in response to a refresh enable signal REF_EN. The refresh enable signal REF_EN may be generated from the command control unit 110. The first cycle signal REF_1X may be a cycle signal for performing a refresh operation for a normal operation. The second cycle signal REF_0.5X may have a cycle shorter than that of the first cycle signal REF_1X, and may be a cycle signal for performing refresh operations in the PPR mode operation.

The refresh control unit 140 may include a refresh cycle adjustment unit 141 and a refresh counter 142.

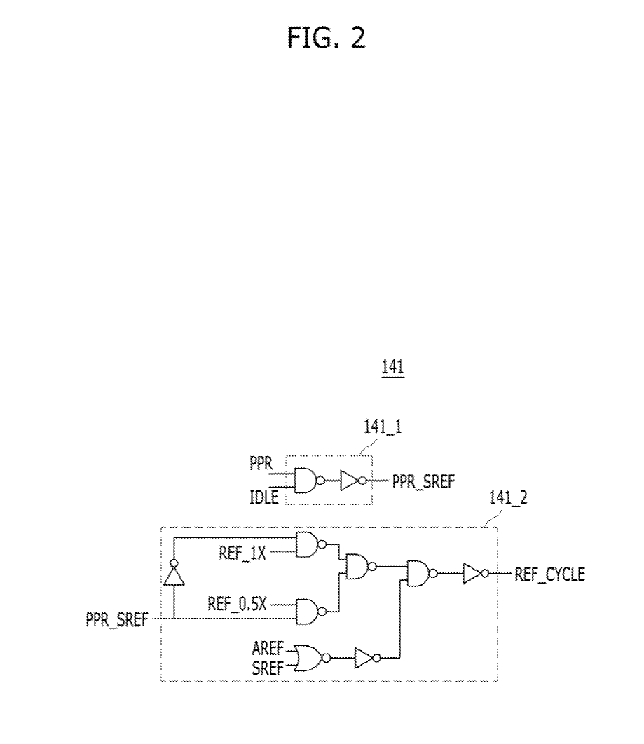

The refresh cycle adjustment unit 141 may generate an internal refresh cycle signal REF_CYCLE in response to the auto-refresh mode signal AREF, the self-refresh mode signal AREF, the PPR mode signal PPR, and the idle signal IDLE. The internal refresh cycle signal REF_CYCLE may be activated when the PPR mode signal PPR and the idle signal IDLE are activated at the same time, and the internal refresh cycle signal REF_CYCLE may be the second cycle signal REF_0.5x. The refresh cycle adjustment unit 141 will be described in detail with reference to FIG. 2.

The refresh counter 142 may receive the internal refresh cycle signal REF_CYCLE as a clock input, count a refresh count reset signal RCNTRST according to the internal refresh cycle signal REF_CYCLE, and generate a plurality of row addresses RA<0:n>. The refresh counter 142 may include a plurality of D flip-flops (not shown).

The row decoder 150 may decode the row addresses RA<0:n>, and generate a row address selection signal (not shown) for sequentially accessing word lines within the cell array 160.

The cell array 160 may perform a refresh operation according to the row address selection signal.

The fuse array 170 (e.g., ARE) may rupture fuses corresponding to fail addresses (not shown) in response to the PPR program signal PPR_PGM, and then perform a boot-up operation in response to a boot-up signal BOOTUP. The fail address may be received from an external controller in a PPR mode, and the boot-up signal BOOTUP may be generated through an internal circuit (not shown) of the semiconductor memory device. The fuse array 170 may complete program and boot-up operations by the PPR program signal PPR_PGM and boot-up signal BOOTUP, and then maintain an idle period by the idle signal IDLE which is activated until the PPR mode is terminated.

That is, when the PPR mode is activated by the PPR mode signal PPR, the fuse array 170 may perform program and boot-up operations in response to the PPR program signal PPR_PGM and boot-up signal BOOTUP, When program and boot-up operations are performed in the PPR mode, for example, when the PPR mode signal PPR is activated and the idle signal IDLE is deactivated, the refresh control unit 140 blocks a refresh signal and does not perform a refresh operation although the refresh signal e.g., an auto-refresh mode signal AREF or a self-refresh mode signal SREF, is inputted thereto. Thereafter, when a boot-up operation has been terminated, the refresh counter 142 generates row addresses RA<0:n>to perform a refresh operation according to an internal refresh cycle signal REF_CYCLE which is generated from the refresh period control unit 141 when the idle signal IDLE is activated, thereby allowing an internal refresh operation to be performed.

In this case, the internal refresh cycle signal REF_CYCLE may be the second cycle signal REF_0.5X. Accordingly, the refresh operation is performed according to the second cycle signal REF_0.5X, which has a cycle shorter than a normal refresh cycle, e.g., the cycle of the first cycle signal REF_1X, during the idle period, and thus the deterioration of data reliability, caused by not performing a refresh operation during the program and boot-up periods, may be prevented.

FIG. 2 is a detailed diagram of the refresh cycle control unit 141 shown in FIG. 1.

Referring to FIG. 2, the refresh cycle control unit 141 may include an internal refresh signal generation unit 141_1 and an internal refresh cycle generation unit 141_2.

The internal refresh signal generation unit 141_1 may generate an internal refresh signal PPR_SREF in response to the PPR mode signal PPR and the idle signal IDLE. The internal refresh signal PPR_SREF may be activated according to the idle signal IDLE activated during an idle period after the PPR mode signal PPR is activated to enter a PPR mode and program and boot-up operations are terminated in the PPR mode.

The internal refresh cycle generation unit 141_2 may selectively output the first cycle signal REF_1X or the second cycle signal REF_0.5X in response to the internal refresh signal PPR_SREF. The first cycle signal REF_1X may be selected and outputted as an internal refresh cycle signal REF_CYCLE for a normal operation, and the second cycle signal REF_0.5X may be selected and outputted as an internal refresh cycle signal REF_CYCLE in a PPR mode. addition, the internal refresh cycle signal REF_CYCLE may be activated when the auto-refresh mode signal AREF or the self-refresh mode signal SREF is activated. That is, when a refresh operation is performed regardless of an auto-refresh operation and a self-refresh operation, the internal refresh cycle signal REF_CYCLE may be generated.

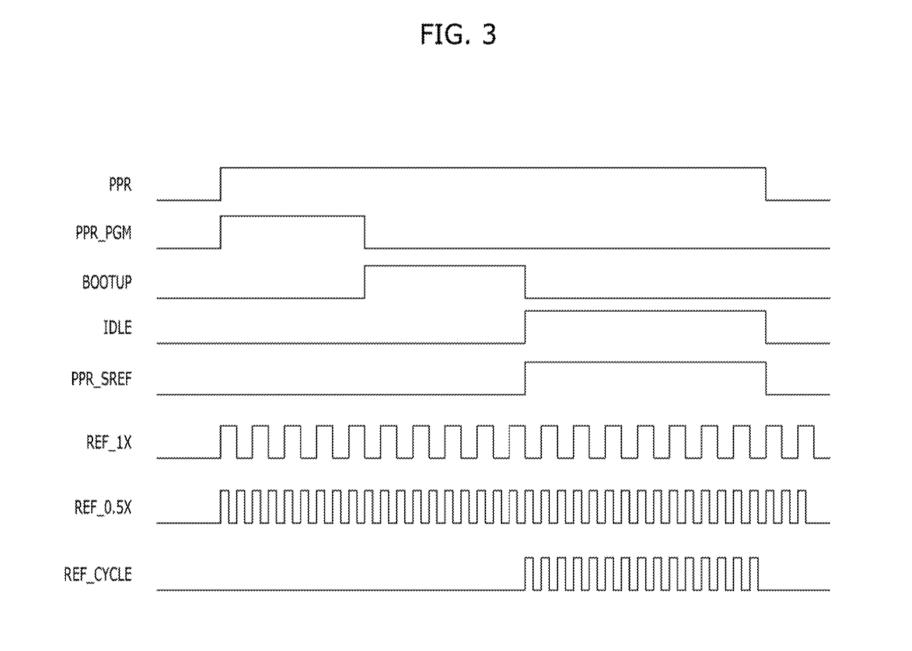

FIG. 3 is a timing diagram for describing an operation of the semiconductor memory device shown in FIG. 1.

Referring to FIGS. 1 to 3, when a PPR mode signal PPR generated from the command control unit 110 is activated, the fuse array control unit 120 may generate a PPR program signal PPR_PGM and an idle signal IDLE. The fuse array 170 may perform a program operation of rupturing fuses corresponding to fail addresses as the PPR program signal PPR_PGM is activated, and then may perform a boot-up operation as a boot-up signal generated by an internal circuit is activated. An internal refresh signal PPR_SREF is activated by the idle signal IDLE activated after the boot-up operation has been terminated; and a second cycle signal REF_0.5X, of a first cycle signal REF_1X and the second cycle signal REF_0.5X which are generated from the refresh cycle generation unit 130, may be selected and used as an internal refresh cycle signal REF_CYCLE when the internal refresh signal PPR_SREF is activated.

That is, in the semiconductor memory device, when PPR program and boot-up operations are performed while the PPR mode signal PPR is activated, the internal refresh cycle signal REF_CYCLE is deactivated so that refresh operations are not performed; and until the PPR mode is terminated from after the boot-up operation has been terminated, i.e., during an idle period, the internal refresh cycle signal REF_CYCLE is activated as the second cycle signal REF_0.5X and thus an internal refresh operation may be performed.

That is, during the idle period, a refresh operation is performed according to the internal refresh cycle signal REF_CYCLE, which has a cycle shorter than the normal refresh cycle, e.g., the cycle of the first cycle signal REF_1X. Accordingly, it is possible to prevent deterioration of data reliability although a refresh signal (not shown) is inputted while performing the PPR program and boot-up operations.

According to the embodiments of the present invention, to compensate for not performing a refresh operation during the program and boot-up periods in a PPR mode, a refresh operation may be performed according to a refresh signal having a cycle shorter than a normal refresh cycle after the boot-up, so that the deterioration of data reliability occurring in the program and boot-up periods may be prevented,

Although various embodiments have been described for illustrative purposes, it will be apparent to those skilled in the art that various changes and modifications may be made without departing from the spirit and scope of the invention as defined in the following claims.

What is claimed is:

1. A semiconductor memory device comprising:
a refresh cycle generation unit capable of generating a first cycle signal and a second cycle signal having a cycle shorter than the first cycle signal; and
a refresh control unit capable of generating a plurality of row addresses based on the first or second cycle signal.

2. The semiconductor memory device of claim 1, wherein the refresh control unit receives a refresh signal, a post package repair mode signal and an idle signal.

3. The semiconductor memory device of claim 2, wherein the refresh control unit includes:
a refresh cycle control unit capable of outputting the first or second cycle signal as an internal refresh cycle signal based on the post package repair mode signal and the idle signal; and
a refresh counter capable of generating the row addresses to perform refresh operations based on the internal refresh cycle signal.

4. The semiconductor memory device of claim 3, wherein the refresh cycle control unit includes:
an internal refresh signal generation unit capable of generating an internal refresh signal based on the post package repair mode signal and the idle signal; and
an internal refresh cycle generation unit capable of outputting the first or second cycle signal based on the internal refresh signal.

5. The semiconductor memory device of claim 2, further comprising:
a fuse array control unit capable of generating the idle signal and a program signal based on the post package repair mode signal; and
a fuse array capable of performing program and boot-up operations based on the program signal and a boot-up signal.

6. The semiconductor memory device of claim 5, wherein the idle signal is activated when the program signal and boot-up signal are deactivated and until the post package repair mode signal is deactivated.

7. The semiconductor memory device of claim2, wherein the refresh signal includes an auto-refresh signal and a self-refresh signal.

8. The semiconductor memory device of claim 2, further comprising:
a command control unit capable of generating the refresh signal and the post package repair mode signal based on an external command.

9. A method of operating a semiconductor memory device, comprising:
generating a program signal and an idle signal based on a post package repair mode signal;
programming a fuse array according to fail addresses based on the program signal;
to performing a boot-up operation on the fuse array; and
performing refresh operations using a first cycle signal or a second cycle signal having a cycle shorter than the first cycle signal, based on the post package repair mode signal and the idle signal.

10. The method of claim 9, wherein the pe or ing of the refresh operations includes:
selecting the first or second cycle signal to output an internal refresh cycle signal based on the post package repair mode signal and the idle signal; and
generating a plurality of row addresses to perform the refresh operations based on the internal refresh cycle signal.

11. The method of claim 10, wherein the selecting of the first or second cycle signal includes:
generating an internal refresh signal based on the post package repair mode signal and the idle signal; and
selecting the first or second cycle signal based on the internal refresh signal to output the internal refresh cycle signal.

12. The method of claim 9, further comprising:
generating the first cycle signal and the second cycle ignal.

13. A semiconductor memory device comprising:
a refresh cycle generation unit capable of generating a first cycle signal and a second cycle signal having a cycle shorter than the first cycle signal;
a fuse array capable of being programmed according to fail addresses during a program period, and performing a boot-up operation during a boot-up period; and
a refresh control unit capable of performing refresh operations using the second cycle signal during an idle period in a post package repair mode.

14. The semiconductor memory device of claim 13, wherein, in a post package repair mode, the refresh operations are not performed during the program and boot-up periods.

15. The semiconductor memory device of claim 13, wherein, in a normal operation, the refresh operations are performed using the first cycle signal.
